(19) United States
(12) Patent Application Publication
(10) Pub. No.: US 2005/0104184 A1
(43) Pub. Date: May 19, 2005

(54) Semiconductor chip package and method

(76) Inventors: Mee-Hyun Ahn, Suwon-si (KR); Jong-Joo Lee, Suwon-si (KR)

Correspondence Address: HARNESS, DICKEY & PIERCE, P.L.C., P.O. BOX 8910, RESTON, VA, 20195, US

(21) Appl. No.: 10/983,576

(22) Filed: Nov. 9, 2004

(30) Foreign Application Priority Data
Nov. 15, 2003 (KR) 2003-80826

(51) Int. Cl. H01L 23/02

(52) U.S. Cl. 257/686

(57) ABSTRACT

A unit semiconductor chip package may includes a semiconductor chip, a first series of bonding pads in a first area, a second series of bonding pads in a second area, a plurality of bonding fingers provided on a substrate and a plurality of bonding wires. Each of the first series of bonding pads may be electrically connected to a corresponding one of the plurality of bonding fingers by one bonding wire and each of the second series of bonding pad may be electrically connected to one of the plurality of bonding fingers by at least two bonding wires or the plurality of bonding wires electrically connecting the first series of bonding pads may be longer and the plurality of bonding wires electrically connecting the second series of bonding pads may be longer or shorter.

### CROSS REFERENCE TO RELATED APPLICATIONS

This application claims priority from Korean Patent Application No. 2003-80826, filed Nov. 15, 2003, the contents of which are hereby incorporated herein by reference in their entirety.

### BACKGROUND OF THE INVENTION

1. Field of the Invention

The present invention relates generally to a semiconductor chip package and method, and more particularly to a bonding pad layout and wire bonding in a semiconductor chip package.

2. Description of Related Art

Semiconductor devices, such as memory integrated circuits, should be higher speed and/or higher density. The performance of a semiconductor device may be influenced by the packaging structure. In particular, a semiconductor chip pad layout and re-routing technology may improve the performance of a semiconductor device.

A multi-chip package (MCP) having semiconductor chips with center bonding pads has been adopted because of the possibility of increasing the memory capacity of a semiconductor package. The conventional semiconductor chip package may provide center bonding pads which are connected to the corresponding bonding finger on a printed circuit board (PCB) by using a longer wire bonding.

Another conventional semiconductor chip package may provide center bonding pads which are re-routed to the peripheral area of the semiconductor chip connected and then the re-routing pads which are connected to the corresponding bonding finger on a PCB using wire bonding. U.S. Pat. No. 6,531,784 discloses conventional integrated circuit chip packages.

FIG. 1 is a plan view of a conventional semiconductor chip package having center bonding pads 15. Center bonding pads 15 may be signal pads, power pads, or ground pads. FIG. 2 is a cross-sectional view of the conventional MCP illustrated in FIG. 1. The conventional MCP having at least two semiconductor chips 10 may typically include long bonding wires 12 which are connected to the corresponding center bonding pad 15 and bonding finger 11 on a PCB 14. The conventional semiconductor chip package may decrease the performance of a semiconductor device due to electrical problems, such as high inductance of the long bonding wires 12 connecting to power and/or ground pads and the bonding fingers 11. The number of bonding wires 12 connecting to power and/or ground pads may be dependent on the number of power and/or ground pads, because an area occupied by the center bonding pads 15 may be restricted to an active area.

FIG. 3 is a plan view of a conventional semiconductor chip package including re-routing pads 16. FIG. 4 is a cross-sectional view of the conventional MCP illustrated in FIG. 3. Referring to FIG. 3, the semiconductor chip package may include shorter bonding wires 12, which are connected to the corresponding re-routing pad 16 on the peripheral area of the semiconductor chip 10 and a bonding finger 11. The semiconductor chip package of FIG. 3 may shorten the length of bonding wires 12 and may broaden the re-routing pads 16, thereby decreasing the inductance problem.

However, such a semiconductor chip package may be difficult to add power and/or ground bonding wires to reduce or prevent crosstalk from occurring at a space between the bonding wires 12. In FIG. 3, a signal path of re-routing pads 16 layout may increase a parasitic capacitance compared to the same dimensioned bonding wires 12 because of a thin insulating layer (not shown) between the re-routing pads 16 and a semiconductor substrate (not shown). Even though the width of re-routing pad 16 may be reduced to decrease a capacitance, the inductance may be increased.

### SUMMARY OF THE INVENTION

Exemplary embodiments of the present invention provide a semiconductor chip package having center bonding pads, thereby improving at least one electrical property of a semiconductor device.

Exemplary embodiments of the present invention provide a semiconductor chip package including at least one semiconductor chip, a first series of bonding pads provided in a first area, a second series of bonding pads provided in a second area, a plurality of bonding fingers provided on a substrate to which the at least one semiconductor chip can be mounted and a plurality of bonding wires electrically connecting the first and second series of bonding pads and the plurality of bonding fingers, wherein each of the first series of bonding pads is electrically connected to a corresponding one of the plurality of bonding fingers by one bonding wire and each of the second series of bonding pad is electrically connected to one of the plurality of bonding fingers by at least two bonding wires.

Exemplary embodiments of the present invention provide a method of connecting a unit semiconductor chip and a substrate including providing a first series of bonding pads in a first area and a second series of bonding pads in a second area, providing a plurality of bonding fingers on the substrate, and electrically connecting each of the first series of bonding pads to a corresponding one of the plurality of bonding fingers by one bonding wire and electrically connecting each of the second series of bonding pad to one of the plurality of bonding fingers by at least two bonding wires.

In an exemplary embodiment, the plurality of bonding wires electrically connecting the first series of bonding pads are longer and the plurality of bonding wires electrically connecting the second series of bonding pads are longer or shorter.

Exemplary embodiments of the present invention provide a unit semiconductor chip package including at least one semiconductor chip, a first series of bonding pads provided in a first area, a second series of bonding pads provided in a second area, a plurality of bonding fingers provided on a substrate to which the at least one semiconductor chip can be mounted, and a plurality of bonding wires electrically connecting the first and second series of bonding pads and the plurality of bonding fingers, wherein the plurality of bonding wires electrically connecting the first series of bonding pads are longer and the plurality of bonding wires electrically connecting the second series of bonding pads are longer or shorter.

Exemplary embodiments of the present invention provide a method of connecting a unit semiconductor chip and a substrate including providing a first series of bonding pads in a first area and a second series of bonding pads in a second area, providing a plurality of bonding fingers on the substrate, and electrically connecting each of the first series of bonding pads to a corresponding one of the plurality of bonding fingers by a longer bonding wire and electrically connecting each of the second series of bonding pad to one of the plurality of bonding fingers by a longer or shorter bonding wire.

In an exemplary embodiment, each of the first series of bonding pads is electrically connected to a corresponding one of the plurality of bonding fingers by one bonding wire and each of the second series of bonding pad is electrically connected to one of the plurality of bonding fingers by at least two bonding wires.

In an exemplary embodiment, the second series of bonding pads are located between the plurality of bonding fingers and the first series of bonding pads.

In an exemplary embodiment, at least one the first or the second series of bonding pads are re-routing pads or connected to re-routing pads.

In an exemplary embodiment, the second series of bonding pads are larger than the first series of bonding pads.

Exemplary embodiments of the present invention provide a multichip semiconductor chip package including at least two of the unit semiconductor chip packages described herein.

### BRIEF DESCRIPTION OF THE DRAWINGS

The present invention will become more readily apparent through the following detailed description of exemplary embodiments of the present invention, made with reference to the attached drawings, in which:

FIG. 1 is a plan view of a conventional semiconductor chip package having center bonding pads;

FIG. 2 is a cross-sectional view of the conventional MCP of FIG. 1;

FIG. 3 is a plan view of a conventional semiconductor chip package having re-routing pads;

FIG. 4 is a cross-sectional view of a conventional MCP of FIG. 3;

FIG. 5 is a plan view of a semiconductor chip package according to an exemplary embodiment of the present invention; and

FIG. 6 is cross-sectional view of a MCP according to an exemplary embodiment of the present invention.

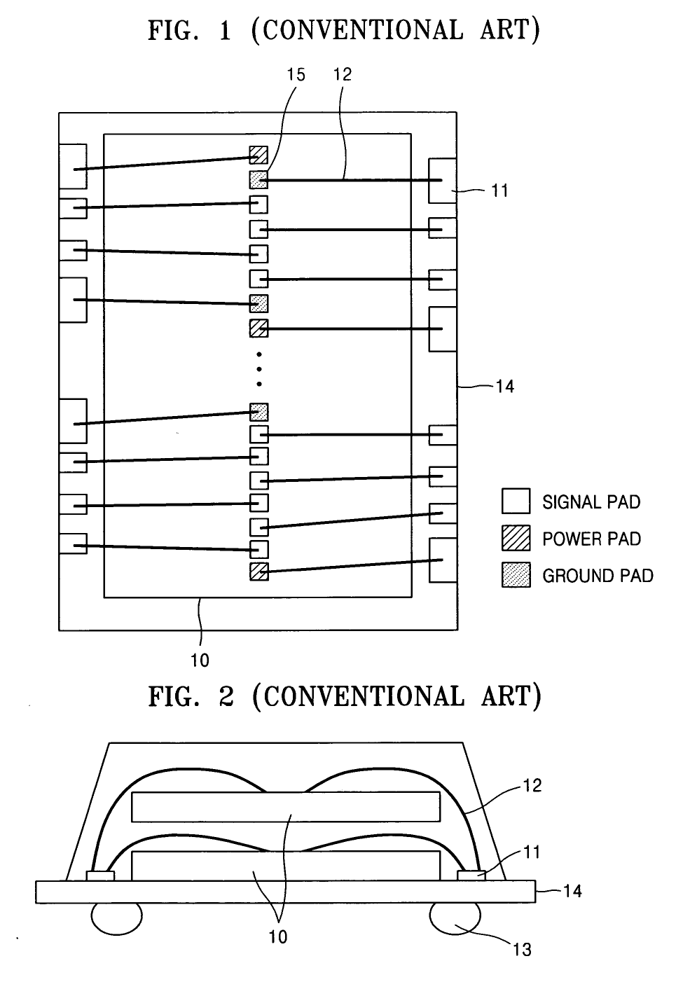

### DETAILED DESCRIPTION OF EXEMPLARY EMBODIMENTS

The present invention will now be described more fully with reference to the accompanying drawings, in which exemplary embodiments of the invention are shown. It should be understood, however, that exemplary embodiments of the present invention described herein can be modified in form and detail without departing from the spirit and scope of the invention. Accordingly, the exemplary embodiments described herein are provided by way of examples and not of limitation, and the scope of the present invention is not restricted to the particular embodiments described herein.

A semiconductor device may have bonding pads on an active surface to allow for an electrical connection. Electrical signals, such as command input signals, data read and data write operation signals may be input and/or output to the semiconductor chip through the bonding pads.

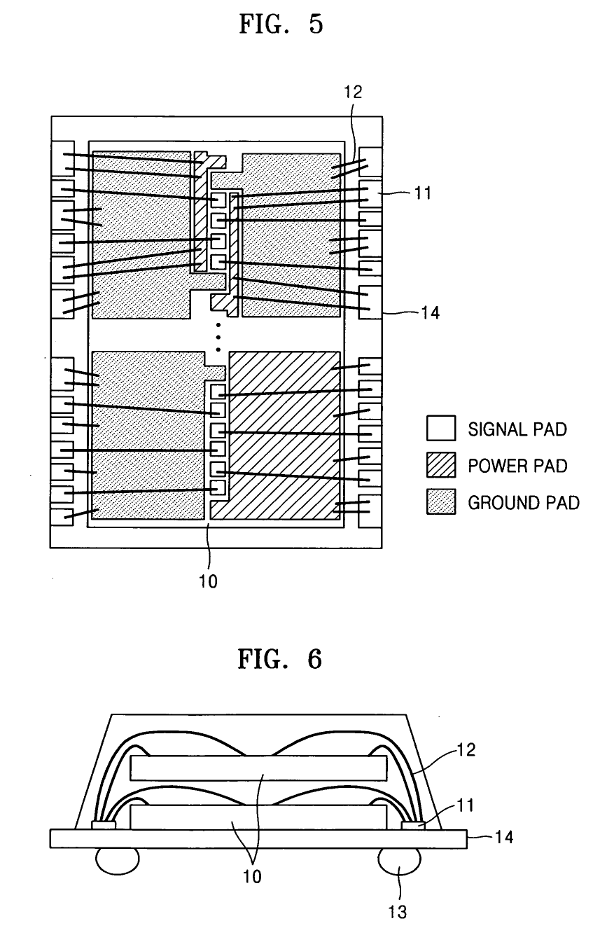

Referring to FIG. 5, according to an exemplary embodiment of the present invention, a semiconductor chip package may include a first series of bonding pads, i.e. signal pads, a second series of bonding pads, i.e. power and/or grounds pads, a plurality of bonding fingers 11 and bonding wires 12. The bonding fingers 11 may be located in a peripheral area, i.e. left, right, top and/or bottom side, surrounding the first series of bonding pads, which may be in a central area, on a PCB 14. The second series of bonding pads, i.e. power and/or grounds pads, may be located between the bonding fingers 11 and the first series of bonding pads.

The first series of bonding pads, for example, signal pads, may be provided in at least one row in a central area of the semiconductor chip 10. The first series of bonding pads may be a part of center bonding pads on the semiconductor chip 10. The second series of bonding pads, for example, power and/or grounds pads, may be provided in another row(s), separate from the first series of bonding pads. Each second series of bonding pads may be larger than each of the first series of bonding pads. The second series of bonding pads may also be a part of center bonding pads on the semiconductor chip 10.

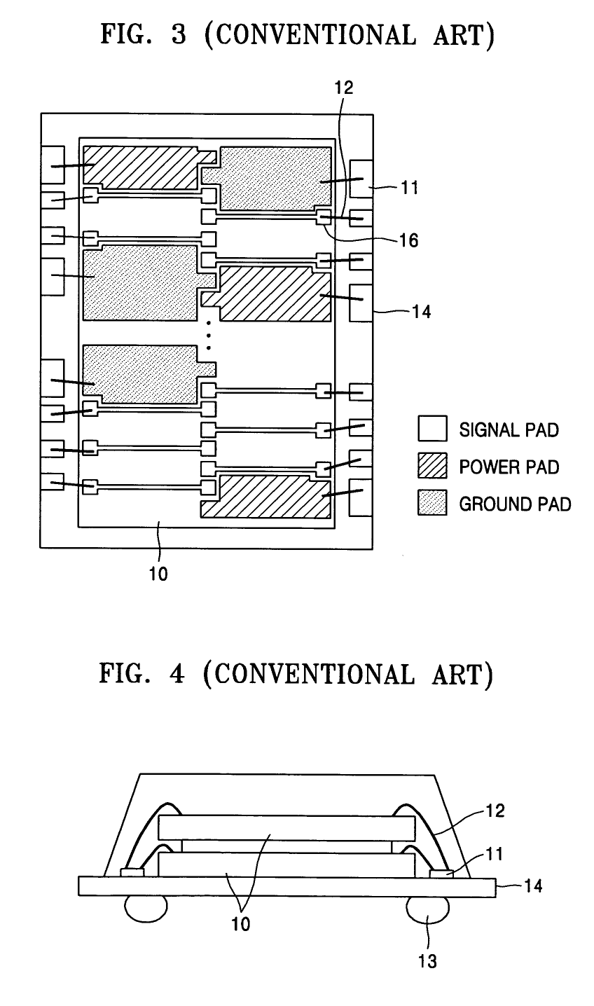

In an alternative exemplary embodiment, the second series of bonding pads may be re-routing pads, for example, similar to the re-routing pads of FIG. 3, made of conductive material, which are electrically connected to a part of the first series of bonding pads. The second series of bonding pads may be located between the bonding fingers 11 and the first series of bonding pads through a re-routing method.

A re-routing method according to exemplary embodiment of the present invention will be described below.

An insulating material, such as oxide and/or polymer, may be formed on exposed bonding pads which are located in a center portion of the semiconductor chip 10. The bonding pads may be re-exposed, for example, by a first photomasking and etching process. A conductive material, for example, metal, may be formed on the exposed bonding pads, and then may be removed by a second photomasking and etching process. The remaining conductive material, for example, the second series of bonding pads, (for example, power and/or grounds pads) may be electrically connected to the part of the center bonding pads.

The center bonding pads without re-routing to the second series of bonding pads, may be exposed as the first series of bonding pads after the second photomasking and etching process. The length of bonding wires 12 may be shortened to be connected to the corresponding bonding finger 11 and the number of bonding wires 12 may be increased to be connected to the same bonding pad.

The bonding fingers 11 may be provided on a substrate 14, for example, a PCB for mounting the semiconductor chip 10 and electrically connected to external terminals 13, for example, solder balls or solder bumps, using a conductive material. The bonding wires 12 may be electrically connected the first and second series of bonding pads and the plurality of bonding fingers 11.

As illustrated in FIG. 5, each of the first series of bonding pads, for example, signal pads, may be electrically connected to a corresponding bonding finger 11 by a longer bonding wire. However, each of the second series of bonding pad, for example, power and/or grounds pads, may be electrically connected to a corresponding bonding finger 11 by a longer or shorter bonding wire.

As also illustrated in FIG. 5, each of the first series of bonding pads, for example, signal pads, may be electrically connected to a corresponding bonding finger 11 by one bonding wire. However, each of the second series of bonding pad, for example, power and/or grounds pads, may be electrically connected to a corresponding bonding finger 11 by at least two bonding wires 12, because each of the second series of bonding pads may be larger than each of the first series of bonding pads. That is, at least two bonding wires 12 connected to each of the second series of bonding pads may be connected to either the same bonding finger or different bonding fingers. The second series of bonding pads which are connected to the corresponding bonding fingers may be used at least two bonding wires 12 in a row, thereby decreasing the inductance of the bonding wires to be transferred power and/or ground and stabling to transfer power and/or ground signals.

In FIG. 5, the second series of bonding pads, i.e. at least two power and/or grounds pads, may be located between the first series of bonding pads and the bonding fingers 11. For example, a power pad and a ground pad among the second series of bonding pads may be located between the first series of bonding pads and the bonding fingers 11. Therefore the bonding wires 12 connected to the power and/or ground pad may exist between the bonding wires 12 connected to the signal pads. In addition, crosstalk of signals transferred by bonding wires 12 connected to the first series of bonding pads may be improved by forming the power and/or ground pad under the bonding wires 12.

Although the second series of bonding pads in FIG. 5 are larger than the first series of bonding pads in two dimensions, the second series of bonding pads could only be larger in one dimension. For example, the second series of bonding pads could be horizontal or vertical strips of approximately the same width as the first series of bonding pads.

Also, although not shown in FIG. 5, either the first series of bonding pads, the second series of bonding pads, or both could be re-routing pads or connected to re-routing pads.

According to an exemplary embodiment of the present invention, there is provided an MCP having at least two semiconductor chips 10. The MCP may be more effective to decrease crosstalk between signals transferred by bonding wires 12 and an inductance of the bonding wires 12 to transfer power and/or ground signals.

In FIG. 6, the MCP may include first and second semiconductor chips 10. The bonding pads of each semiconductor chip 10 may be arranged as illustrated in FIG. 5.

As described above, the first semiconductor chip 10 may include a first series of bonding pads which are provided in a first area, a second series of bonding pads which are provided in a second row. Each of the second series of bonding pad may be larger than each of the first series of bonding pads. The second semiconductor chip 10 may include a third series of bonding pads which are provided in a row and a fourth series of bonding pads which are provided in another row compared with the third series of bonding pads. Each of the fourth series of bonding pad may be larger than each of the third series of bonding pads.

The first and third series of bonding pads may be signal pads and the second and fourth series of bonding pads may be power and/or grounds pads. The second and fourth series of bonding pads may be re-routing pads, made of a conductive material which are electrically connected to a part of the first and third series of bonding pads.

As illustrated in FIGS. 5 and 6, the bonding fingers 11 may be located a peripheral area, i.e. left, right, top, bottom side, on a PCB 14. The second and fourth series of bonding pads may be located between the bonding fingers 11 and the first series of bonding pads and between the bonding fingers 11 and the third series of bonding pads.

The second and fourth series of bonding pads, for example, at least two power and/or grounds pads, may be located between the first and third series of bonding pads and the bonding fingers 11. Each of the first and third series of bonding pad may be electrically connected the corresponding bonding finger 11 by one bonding wire. Each of the second and fourth series of bonding pad may be electrically connected to the corresponding bonding finger 11 by at least two bonding wires 12. That is, at least two bonding wires 12 connected to the second and fourth series of bonding pad may be connected to either the same bonding finger or different bonding fingers.

As mentioned above, exemplary embodiments of the present invention may use semiconductor chips with center bonding pads and may improve at least one electrical property, for example, inductance and/or capacitance, and/or reduce re-routing problems relative to only using the center bonding pads.

Although the invention has been described with reference to various aspects and exemplary embodiments thereof, it will be apparent to those of ordinary skill in the art that various modifications and adaptations to the described embodiments may be made without departing from the spirit and scope of the invention as defined in the appended claims.

1. A unit semiconductor chip package comprising:
at least one semiconductor chip;
a first series of bonding pads provided in a first area;
a second series of bonding pads provided in a second area;
a plurality of bonding fingers provided on a substrate to which the at least one semiconductor chip can be mounted; and
a plurality of bonding wires electrically connecting the first and second series of bonding pads and the plurality of bonding fingers;
wherein each of the first series of bonding pads is electrically connected to a corresponding one of the plurality of bonding fingers by one bonding wire and each of the second series of bonding pad is electrically connected to one of the plurality of bonding fingers by at least two bonding wires.

2. The unit semiconductor chip package of claim 1, wherein the second series of bonding pads are located between the plurality of bonding fingers and the first series of bonding pads.

3. The unit semiconductor chip package of claim 1, wherein the first series of bonding pads are signal pads.

4. The unit semiconductor chip package of claim 1, wherein the second series of bonding pads are either power pads or ground pads.

5. The unit semiconductor chip package of claim 1, wherein at least one the first or the second series of bonding pads are re-routing pads or connected to re-routing pads.

6. The unit semiconductor chip package of claim 1, wherein the second series of bonding pads are larger than the first series of bonding pads.

7. The unit semiconductor chip package of claim 1, wherein at least two second series of bonding pads are located between the plurality of bonding fingers and the first series of bonding pads.

8. The unit semiconductor chip package claim 1, wherein the plurality of bonding wires electrically connecting the first series of bonding pads are longer and the plurality of bonding wires electrically connecting the second series of bonding pads are longer or shorter.

9. The unit semiconductor chip package of claim 1, wherein the at least two bonding wires connected to the each of the second series of bonding pad are connected to the same bonding finger.

10. The unit semiconductor chip package of claim 1, wherein the at least two bonding wires connected to each of the second series of bonding pad are separately connected to the plurality of bonding fingers.

11. A unit semiconductor chip package comprising:
at least one semiconductor chip;
a first series of bonding pads provided in a first area;
a second series of bonding pads provided in a second area;
a plurality of bonding fingers provided on a substrate to which the at least one semiconductor chip can be mounted; and
a plurality of bonding wires electrically connecting the first and second series of bonding pads and the plurality of bonding fingers;
wherein the plurality of bonding wires electrically connecting the first series of bonding pads are longer and the plurality of bonding wires electrically connecting the second series of bonding pads are longer or shorter.

12. The unit semiconductor chip package of claim 11, wherein the second series of bonding pads are located between the plurality of bonding fingers and the first series of bonding pads.

13. The unit semiconductor chip package of claim 11, wherein the first series of bonding pads are signal pads.

14. The unit semiconductor chip package of claim 11, wherein the second series of bonding pads are either power pads or ground pads.

15. The unit semiconductor chip package of claim 11, wherein at least one of the first or the second series of bonding pads are re-routing pads or connected to re-routing pads.

16. The unit semiconductor chip package of claim 11, wherein the second series of bonding pads are larger than the first series of bonding pads.

17. The unit semiconductor chip package of claim 11, wherein at least two second series of bonding pads are located between the plurality of bonding fingers and the first series of bonding pads.

18. The unit semiconductor chip package claim 1, wherein each of the first series of bonding pads is electrically connected to a corresponding one of the plurality of bonding fingers by one bonding wire and each of the second series of bonding pad is electrically connected to one of the plurality of bonding fingers by at least two bonding wires.

19. The unit semiconductor chip package of claim 11, wherein the at least two bonding wires connected to the each of the second series of bonding pad are connected to the same bonding finger.

20. The unit semiconductor chip package of claim 11, wherein the at least two bonding wires connected to each of the second series of bonding pad are separately connected to the plurality of bonding fingers.

21. A multichip semiconductor chip package including at least two of the unit semiconductor chip packages of claim 1.

22. A multichip semiconductor chip package including at least two of the unit semiconductor chip packages of claim 11.

23. A method of connecting a unit semiconductor chip and a substrate comprising:
providing a first series of bonding pads in a first area and a second series of bonding pads in a second area;
providing a plurality of bonding fingers on the substrate; and
electrically connecting each of the first series of bonding pads to a corresponding one of the plurality of bonding fingers by one bonding wire and electrically connecting each of the second series of bonding pad to one of the plurality of bonding fingers by at least two bonding wires.

24. A method of connecting a unit semiconductor chip and a substrate comprising:
providing a first series of bonding pads in a first area and a second series of bonding pads in a second area;
providing a plurality of bonding fingers on the substrate; and
electrically connecting each of the first series of bonding pads to a corresponding one of the plurality of bonding fingers by a longer bonding wire and electrically connecting each of the second series of bonding pad to one of the plurality of bonding fingers by a longer or shorter bonding wire.

25. A unit semiconductor chip package manufactured according to the method of claim 23.

26. A unit semiconductor chip package manufactured according to the method of claim 24.
